(19) United States
(12) Patent Application Publication
(10) Pub. No.: US 2016/0319463 A1
(43) Pub. Date: Nov. 3, 2016

(54) METHOD OF MANUFACTURING TRANSPARENT ELECTRODE USING ELECTROSPINNING METHOD, AND TRANSPARENT ELECTRODE FORMED USING SAME

(71) Applicant: UNIST (ULSAN NATIONAL INSTITUTE OF SCIENCE AND TECHNOLOGY), Ulsan (KR)

(72) Inventors: jang-ung PARK, Ulsan (KR); byung gwan HYUN, Bucheon-si (KR); byeong-wan AN, Yongin-si (KR)

(73) Assignee: UNIST (ULSAN NATIONAL INSTITUTE OF SCIENCE AND TECHNOLOGY), Ulsan (KR)

(21) Appl. No.: 15/101,418

(22) PCT Filed: Dec. 6, 2013
(86) PCT No.: PCT/KR2013/011275

§ 371 Date: Jul. 14, 2016

(30) Foreign Application Priority Data
Dec. 5, 2013 (KR) 10-2013-0150530

(51) Int. Cl. D01D 5/00; C01B 31/02; B29C 47/06; C01B 31/04; H01L 33/42; B29C 47/00

(52) U.S. Cl. CPC D01D 5/0046; H01L 33/42; B29C 47/0014; B29C 47/0076; D01D 5/0092; B29C 47/065; C01B 31/04; C01B 31/0446; C01B 31/0226; H01L 2933/0016; D10B 2401/20; D10B 2401/061; D10B 2101/20; B29L 2031/731

(57) ABSTRACT

The present invention provides a method of manufacturing a transparent electrode using an electrospinning method. The method of manufacturing a transparent electrode according to an embodiment of the present invention includes: spinning a nanomaterial and a polymer material together on a first substrate to form a coaxial double-layered fiber including the nanomaterial and the polymer material; and removing the polymer material from the coaxial double-layered fiber to form a transparent electrode including the nanomaterial.

### TECHNICAL FIELD

The present invention relates to a transparent electrode, and more particularly, to a method of manufacturing a transparent electrode using an electrospinning method, and a transparent electrode formed using the same.

### BACKGROUND ART

Owing to recent developments in smart electronic apparatuses, research into flexible display apparatuses or stretchable display apparatuses that replace existing solid display apparatuses, is being carried out. A transparent electrode having transparency is required in display apparatuses, and an indium tin oxide (ITO) has been usually used to form the transparent electrode. However, such an ITO has low flexibility or elasticity. Thus, it is difficult to apply the ITO to flexible display apparatuses.

In order to overcome a limitation of the ITO, a transparent electrode including another material, for example, a transparent electrode using graphene or silver (Ag) nanowires has been developed. However, according to the current research result, there are limitations that a process of manufacturing the transparent electrode using graphene or Ag nanowires is complicated, the reliability of a product is low and the product is expensive. Korean Patent Registration No. 10-1197986 discloses related technologies.

### DETAILED DESCRIPTION OF THE INVENTION

### Technical Problem

The present invention provides a method of manufacturing a transparent electrode using an electrospinning method.

The present invention also provides a transparent electrode formed using the method of manufacturing the transparent electrode using the electrospinning method.

The present invention also provides an electrospinning apparatus for manufacturing a transparent electrode using an electrospinning method.

However, these objectives are exemplary, and the technical spirit of the present invention is not limited thereto.

### Technical Solution

According to an aspect of an embodiment, a method of manufacturing a transparent electrode using an electrospinning method, the method includes: spinning a nanomaterial and a polymer material together on a first substrate to form a coaxial double-layered fiber including the nanomaterial and the polymer material; and removing the polymer material from the coaxial double-layered fiber to form a transparent electrode including the nanomaterial.

According to an aspect of another embodiment, a transparent electrode is manufactured by the above-described method of manufacturing the transparent electrode.

According to an aspect of another embodiment, an electrospinning apparatus for manufacturing a transparent electrode, in which a first spinning solution and a second spinning solution that are different from each other are spinned together to form a coaxial double-layered fiber, the electrospinning apparatus includes: a first spinning nozzle spinning the first spinning solution and disposed outside a spinning nozzle; and a second spinning nozzle spinning the second spinning solution, being surrounded by the first spinning nozzle and disposed inside the first spinning nozzle.

### Effect of the Invention

In a method of manufacturing a transparent electrode using an electrospinning method according to the technical spirit of the present invention, a coaxial double-layered fiber can be formed by spinning a nanomaterial and a polymer material together using the electrospinning method, and the transparent electrode can be provided by removing the polymer material.

By using an electrospinning method according to the technical spirit of the present invention, a transparent electrode having flexibility or elasticity can be provided in a simple and economical process, and a flexible display apparatus or a stretchable display apparatus can be easily implemented using the transparent electrode.

A transparent electrode according to the technical spirit of the present invention can be applied to the flexible display apparatus or the stretchable display apparatus. For example, a display apparatus including the transparent electrode is attached to a contact lens so that a feeling of wearing can be improved and the display apparatus can be conveniently used. Also, by using the feature of the transparent electrode according to the technical spirit of the present invention for providing elasticity, the size of a display can be adjusted to a user's desired size. By using the feature of the transparent electrode according to the technical spirit of the present invention for providing transparency, a transparent display can be provided. Thus, a touch screen panel having elasticity and being transparent can be provided. The transparent electrode according to the technical spirit of the present invention can increase portability, an aesthetic property, and spatial application of the display apparatus.

The above-described effects of the present invention are exemplary, and the scope of the invention is not limited by these effects.

### DESCRIPTION OF THE DRAWINGS

FIG. 1 is a flowchart illustrating a method of manufacturing a transparent electrode according to an embodiment of the present invention.

FIG. 2 is a schematic view illustrating an electrospinning apparatus that performs the method of manufacturing a transparent electrode, according to an embodiment of the present invention;

FIG. 3 is an enlarged cross-sectional view of a spinning nozzle of the electrospinning apparatus of FIG. 2, according to an embodiment of the present invention;

FIG. 4 is a schematic view illustrating a shape in which a spinning solution is spinned by the electrospinning apparatus that performs the method of manufacturing the transparent electrode of FIG. 1, according to an embodiment the present invention.

FIGS. 5 through 9 are schematic views illustrating a method of manufacturing a transparent electrode at each process step, according to an embodiment of the present invention.

FIG. 11 is a schematic view illustrating a process of manufacturing a transparent electrode according to an embodiment of the present invention.

FIG. 12 is a schematic view illustrating a transparent electrode formed by the method of manufacturing the transparent electrode of FIG. 1, according to an embodiment of the present invention.

FIG. 13 is a graph showing transmittance versus an optical wavelength of the transparent electrode manufactured by the method of manufacturing the transparent electrode, according to an embodiment of the present invention.

FIG. 14 is a graph showing a change in resistances according to a degree of tension of the transparent electrode manufactured by the method of manufacturing the transparent electrode, according to an embodiment of the present invention.

FIGS. 15 through 30 are optical microscopic photos showing the transparent electrode manufactured by the method of manufacturing the transparent electrode, according to an embodiment of the present invention.

### MODE OF THE INVENTION

Hereinafter, exemplary embodiments of the present invention will be described with reference to the attached drawings. Embodiments of the present invention are provided to those skilled in the art so as to more completely describe the technical spirit of the invention. The following embodiments may be modified in several different shapes, and the scope of the technical spirit of the invention is not limited to the following embodiments. Rather, these embodiments are provided to make this disclosure more faithful and complete and to fully transfer the technical spirit of the invention to those skilled in the art. Like reference numerals refer to like elements. Furthermore, various elements and regions in the drawings are schematically drawn. Thus, the technical spirit of the invention is not limited by a relative size or interval drawn in the attached drawings.

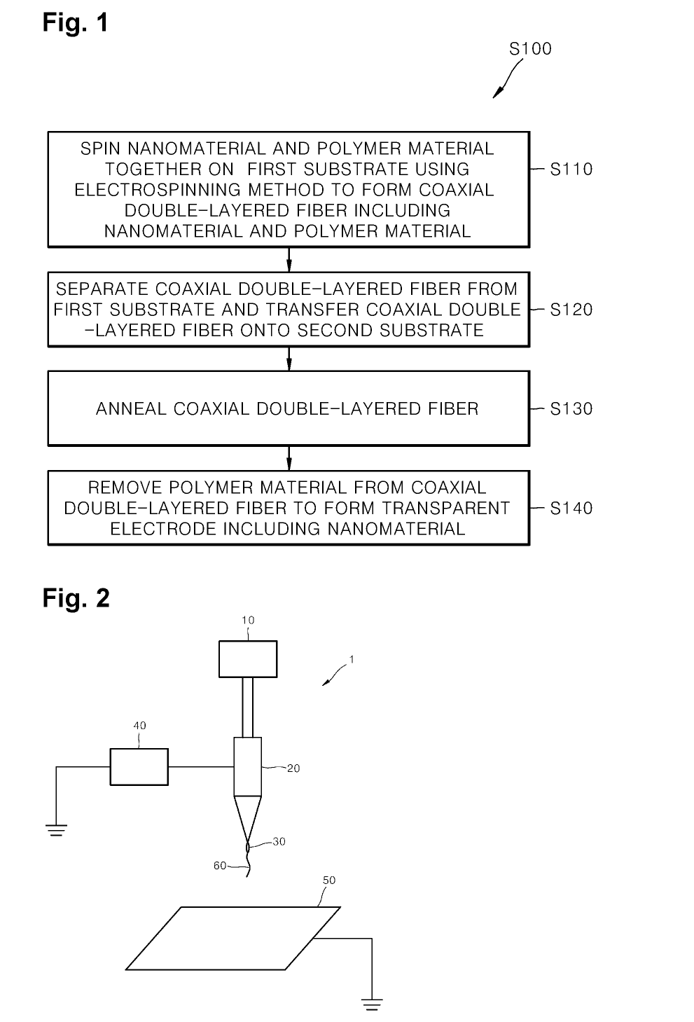

FIG. 1 is a flowchart illustrating a method S100 of manufacturing a transparent electrode according to an embodiment of the invention.

Referring to FIG. 1, the method S100 of manufacturing the transparent electrode includes: spinning a nanomaterial and a polymer material together on a first substrate using an electrospinning method to form a coaxial double-layered fiber including the nanomaterial and the polymer material (S110); separating the coaxial double-layered fiber from the first substrate to transfer the separated coaxial double-layered fiber onto a second substrate (S120); annealing the coaxial double-layered fiber (S130); and removing the polymer material from the coaxial double-layered fiber to form a transparent electrode including the nanomaterial (S140).

In forming of the coaxial double-layered fiber, the coaxial double-layered fiber having a shape of a coaxial cylinder in which a nanomaterial layer formed from the nanomaterial is disposed inside the coaxial double-layered fiber and a polymer material layer formed from the polymer material is surrounded by the nanomaterial layer and disposed outside the nanomaterial layer, may be implemented.

The coaxial double-layered fiber may be implemented as a coaxial double-layered fiber having a shape of a coaxial cylinder in which a polymer material layer formed from the polymer material is disposed inside the coaxial double-layered fiber and a nanomaterial layer formed from the nanomaterial is surrounded by the polymer material layer and disposed outside the polymer material layer.

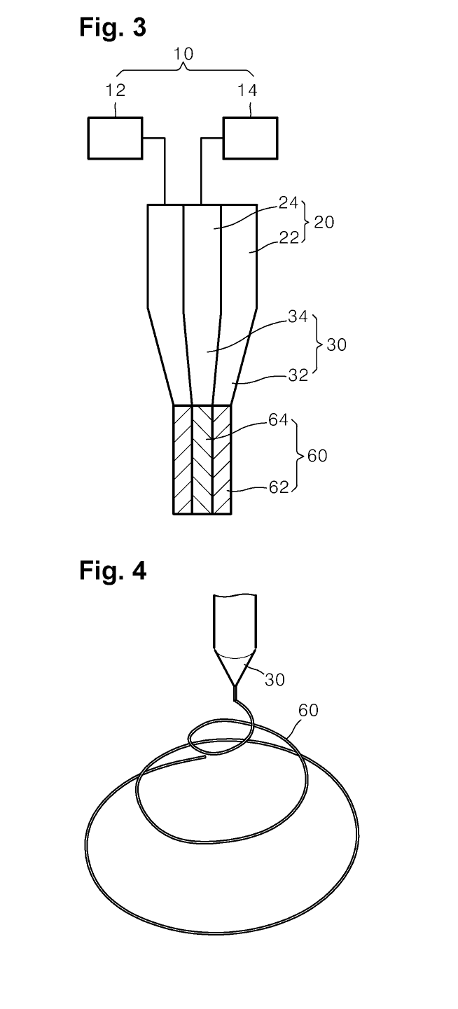

FIG. 2 is a schematic view illustrating an electrospinning apparatus 1 that performs the method of manufacturing the transparent electrode, according to an embodiment of the present invention. FIG. 3 is an enlarged cross-sectional view of a spinning nozzle 20 of the electrospinning apparatus 1 of FIG. 2, according to an embodiment of the present invention.

Referring to FIGS. 2 and 3, the electrospinning apparatus 1 for manufacturing a transparent electrode includes a spinning solution tank 10, the spinning nozzle 20, a spinning nozzle tip 30, an external power supply 40, and a collector substrate 50. The electrospinning apparatus 1 for manufacturing the transparent electrode may be used for other purposes than a purpose for manufacturing the transparent electrode.

The spinning solution tank 10 may store a spinning solution 60 in which spinning is to be required. The spinning solution tank 10 may pressurize the spinning solution 60 using a built-in pump (not shown) and may provide the spinning solution 60 to the spinning nozzle 20. The spinning solution tank 10 may include a first spinning solution tank 12 and a second spinning solution tank 14. The first spinning solution tank 12 and the second spinning solution tank 14 may store different spinning solutions. For example, the first spinning solution tank 12 may store a first spinning solution 62, for example, a polymer solution including a polymer material, and the second spinning solution tank 14 may store a second spinning solution 64, for example, a nanomaterial solution including a nanomaterial.

The spinning nozzle 20 may spin the spinning solution 60 including the first spinning solution 62 and the second spinning solution 64 supplied from the spinning solution tank 10, through the spinning nozzle tip 30 disposed at one end of the spinning nozzle 20. The spinning nozzle 20 may include a first spinning nozzle 22 and a second spinning nozzle 24. The first spinning nozzle 22 may be disposed outside the spinning nozzle 20. The second spinning nozzle 24 may be surrounded by the first spinning nozzle 22 and disposed inside the first spinning nozzle 22.

The spinning nozzle tip 30 may spin the spinning solution 60 due to a voltage applied by the external power supply 40 after the spinning solution 60 is pressurized by the pump and an internal nozzle tube is filled with the spinning solution 60. The spinning nozzle tip 30 may include a first spinning nozzle tip 32 and a second spinning nozzle tip 34. The first spinning nozzle tip 30 may be connected to the first spinning nozzle 22 and disposed outside the spinning nozzle tip 30. The second spinning nozzle tip 30 may be connected to the second spinning nozzle 24, surrounded by the first spinning nozzle tip 32 and disposed inside the first spinning nozzle tip 32.

The external power supply 40 may provide a voltage so that the spinning solution 60 may be spinned on the spinning nozzle 20. The voltage may be changed according to the type of the spinning solution 60 and a spinning amount and may be a direct current (DC) or an alternating current (AC) in the range of about 100 V to about 30000 V, for example. As described above, the voltage applied by the external power supply 40 may spin the spinning solution 60 filled in the spinning nozzle tip 30.

The collector substrate 50 is disposed below the spinning nozzle 20 and accommodates the spinning solution 60 to be spinned. The collector substrate 50 may be grounded and thus may have a ground voltage, for example, a voltage of 0 V. Alternatively, the collector substrate 50 may have an opposite voltage to a voltage of the spinning nozzle 20. The position relationship between the collector substrate 50 and the spinning nozzle 20 is exemplary, and the technical spirit of the invention is not limited thereto. For example, the case where the collector substrate 50 is disposed above the spinning nozzle 20 and the spinning solution 60 to be spinned from the spinning nozzle 20 is spinned in an upward direction, is also included in the technical spirit of the invention. For example, the case where the collector substrate 50 is disposed horizontally to the spinning nozzle 20 and the spinning solution 60 to be spinned from the spinning nozzle 20 is spinned in a horizontal direction, is also included in the technical spirit of the invention. The collector substrate 50 may be horizontally to or on the same space axis as the spinning nozzle 20.

Due to the external power supply 40, the spinning nozzle 20 and the spinning nozzle tip 30 are charged with a positive voltage or negative voltage. Thus, the spinning solution 60 is also charged so that there is a voltage difference between the spinning nozzle tip 30 and the collector substrate 50 grounded or having an opposite voltage. When a voltage is applied to the spinning nozzle 20 and the spinning nozzle tip 30 due to the external power supply 40, the spinning solution 60 at an end of the spinning nozzle tip 30 may have a shape of a cone, such as a tailor cone. In this case, an electric field in the range of about 50000 V/m to about 150000 V/m may be formed between the spinning nozzle tip 30 and the spinning solution 60. Due to the voltage difference, the spinning solution 60 may be spinned on the collector substrate 50 and accommodated therein. This spinning principle may be referred to as electro-hydro dynamic inkjet or electrospinning.

As the flow rate of the spinning solution 60 and the voltage difference between the spinning nozzle tip 30 and the collector substrate 50 are controlled, the diameter and length of a fiber accommodated in the collector substrate 50 due to spinning of the spinning solution 60 may be controlled. For example, the fiber may have the thickness in the range of about 50 nm to 1 μm and the length in the range of about several μm to several hundreds of μm.

In detail, the first spinning solution 62 may be spinned from the first spinning solution tank 12 through the first spinning nozzle 22 and the first spinning nozzle tip 32. The second spinning solution 64 may be spinned from the second spinning solution tank 14 through the second spinning nozzle 24 and the second spinning nozzle tip 34.

The first spinning solution 62 and the second spinning solution 64 may be simultaneously spinned and may have same spinning lengths. Also, the first spinning solution 62 to be spinned may be spinned while surrounding the outside of the second spinning solution 64, and the second spinning solution 64 may be surrounded by the first spinning solution 62 and disposed inside the first spinning solution 62. Thus, the fiber accommodated in the collector substrate 50 may have a shape in which the second spinning solution 64 is inside the fiber and the first spinning solution 62 surrounds the outside of the second spinning solution 64. That is, the fiber may include a coaxial double-layered fiber.

The following conditions may be required so that the coaxial double-layered fiber may be easily formed. The first spinning solution 62 and the second spinning solution 64 are not supposed to be mixed with each other. An injection speed of the first spinning solution 62 outside the second spinning solution 64 may be equal to or greater than the injection speed of the second spinning solution 64 inside the first spinning solution 62. At least one of the first spinning solution 62 and the second spinning solution 64 is required to have conductivity. Also, a vapor pressure of the first spinning solution 62 and a vapor pressure of the second spinning solution 64 may be equal to or similar to each other. Also, the viscosity of the first spinning solution 62 has to be equal to or greater than the viscosity of the second spinning solution 64.

As the injection speed of the second spinning solution 64 disposed inside the fiber increases, a diameter corresponding to the second spinning solution 64 disposed inside the fiber is increased, but an outer diameter of the fiber may not be changed or greatly changed. That is, in this case, a dimeter corresponding to the first spinning solution 62 disposed outside the fiber may be reduced.

For example, the injection speed of the first spinning solution 62 may be in the range of 1.5 ml/hour to 3.5 ml/hour, the injection speed of the second spinning solution 64 may be in the range of 0.1 ml/hour to 1.5 ml/hour, and the entire injection speed may be in the range of 2.0 ml/hour to 4.0 ml/hour. However, this injection speed is exemplary, and the technical spirit of the invention is not limited thereto.

Although, in the current embodiment, each of the spinning nozzle 20 and the spinning nozzle tip 30 is configured to have divided regions according to the type of the spinning solution, the technical spirit of the invention is not limited thereto. For example, the case where the first spinning solution 62 and the second spinning solution 64 are injected and spinned together into and on the spinning nozzle 20 and the spinning nozzle tip 30 that include no divided regions, is also included in the technical spirit of the invention.

FIG. 4 is a schematic view illustrating a shape in which a spinning solution is spinned by the electrospinning apparatus 1 that performs the method S100 of manufacturing the transparent electrode of FIG. 1, according to an embodiment the present invention.

Referring to FIG. 4, the spinning nozzle tip 30 may spin the spinning solution 60 including the first spinning solution 62 and the second spinning solution 64 entirely in a linear form, for example, in a wire or rod form. This spinning may be referred to as a spinning mode. Although not shown, the spinning nozzle tip 30 may spin the spinning solution 60 in a spray form. This spinning may be referred to as a spray mode.

The spinning solution 60 may be spinned in different forms according to its own material properties, such as the viscosity of a solution, a weight ratio of a solute in the solution, types of the solute and the solution, and molecular weights of the solute and a solvent. Also, the spinning solution 60 may be spinned in different forms according to the magnitude of an applied voltage. For example, in FIG. 3, the case where the spinning solution 60 has relatively high viscosity or a relatively low voltage is applied, may be included. In case of the spray mode, the case where the spinning solution 60 has relatively low viscosity or a relatively high voltage is applied, may be included.

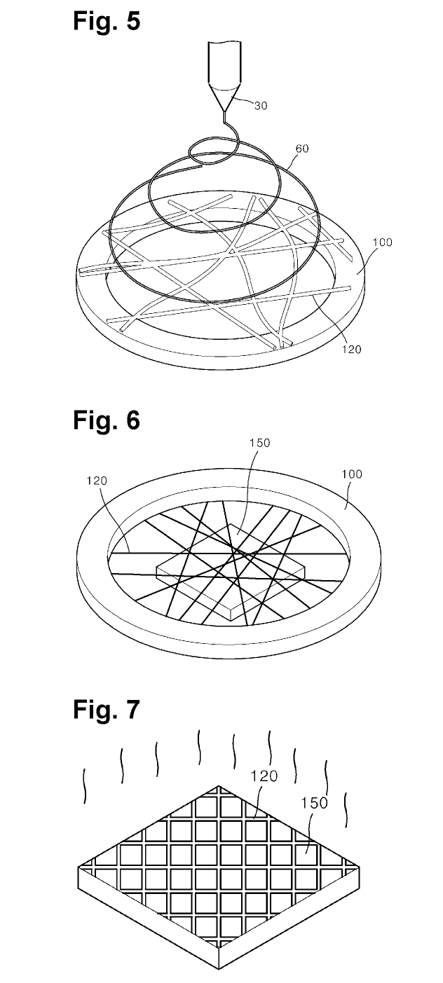

FIGS. 5 through 9 are schematic views illustrating the method S100 of manufacturing the transparent electrode, according to an embodiment of the present invention. The order of manufacturing process steps to be described with reference to FIGS. 5 through 9 is exemplary, and the case where the manufacturing process steps are performed in a different order, is also included in the technical spirit of the invention.

Referring to FIG. 5, an operation S110 of forming a coaxial double-layered fiber 120 on the first substrate 100 of FIG. 1 is performed.

The above operation may be performed by spinning the spinning solution 60 on the first substrate 100 using an electrospinning method. As described above, the spinning solution 60 may include the first spinning solution 62 and the second spinning solution 64.

Specifically, the first substrate 100 is prepared. The first substrate 100 may be a collector substrate 50 of FIG. 2 or a separate substrate disposed on the collector substrate 50. The first substrate 100 may include a conductive material, for example, a metal material. In this case, the first substrate 100 may have the same voltage state as a voltage state of the collector substrate 50 while performing electrospinning. Also, the first substrate 100 may include an insulating material, for example, glass or a polymer material.

The first substrate 100 may have a shape in which a central part of the first substrate 100 is perforated and which includes outer edges. For example, the first substrate 100 may be a free standing substrate that does not support a lower side of an object to be formed. In detail, the first substrate 100 may include all types of substrates that may form an object having a free standing structure. The first substrate 100 may have a ring shape in which a central part of the first substrate 100 is perforated and outer edges thereof are connected to one another, as illustrated in FIG. 5. Also, the first substrate 100 may have a shape of a horseshoe in which a central part of the first substrate 100 is perforated and outer edges thereof are not connected to one another. Also, the first substrate 100 may have a polygonal shape in which a central part of the first substrate 100 is perforated and outer edges thereof are connected to one another, or a polygonal shape in which a central part of the first substrate 100 is perforated and outer edges thereof are not connected to one another.

However, the shape of the first substrate 100 is exemplary, and the technical spirit of the invention is not limited thereto. For example, the case where the first substrate 100 has a shape of a flat plate having no perforated region, is also included in the technical spirit of the invention. For example, the case where the first substrate 100 has a plate shape, a drum shape, parallel rods, a plurality of crossing rods or a grid shape, is also included in the technical spirit of the invention.

Subsequently, a spinning solution 60 is spinned from the spinning nozzle tip 30 using an electrospinning method using the electrospinning apparatus 1 of FIG. 2. A voltage used in the electrospinning method may be changed according to the type of the spinning solution 60, the type of the first substrate 100, a process environment, and the like and may be in the range of about 100 V to about 30000 V, for example.

The spinning solution 60 may include a first spinning solution 62 including a polymer solution in which a polymer material is dissolved in a solvent, and a second spinning solution 64 including a nanomaterial solution in which a nanomaterial is dissolved in a solvent. The first spinning solution 62 may be spinned from the first spinning nozzle tip 32, and together, the second spinning solution 64 may be spinned from the second spinning nozzle tip 34. Thus, the spinning solution 60 may be configured so that the second spinning solution 64 is disposed inside the spinning solution 60 and the first spinning solution 62 is disposed outside the second spinning solution 64. The spinned spinning solution 60 may have a gel state and may be spinned in a linear form illustrated in FIG. 3.

The spinning solution 60 may be seated on the first substrate 100 and may form a coaxial double-layered fiber 120. The coaxial double-layered fiber 120 may have a shape of a coaxial cylinder in which a nanomaterial layer 140 formed from the nanomaterial is disposed inside the coaxial double-layered fiber 120 and a polymer material layer 130 formed from the polymer material is surrounded by the nanomaterial layer 140 and disposed outside the nanomaterial layer 140.

The coaxial double-layered fibers 120 may be arranged to configure a one-dimensional, two-dimensional, or three-dimensional network structure formed in which coaxial double-layered fibers 120 overlap one another on the first substrate 100 and are connected to one another. For example, the coaxial double-layered fiber 120 may form a one-dimensional network structure in which a plurality of linear structures overlap one another in parallel and are connected to one another in one linear shape. For example, the coaxial double-layered fiber 120 may form a two-dimensional conductive network structure in which a plurality of linear structures overlap one another at a predetermined angle and are connected to one another in one planar shape. For example, the coaxial double-layered fiber 120 may form a three-dimensional conductive network structure in which a plurality of linear structures overlap one another at a predetermined angle and are connected to one another in one three-dimensional shape. As the coaxial double-layered fiber 120 is configured of the conductive network structure, the transparent electrode 160 may enable a more smooth current flow. Also, for example, the coaxial double-layered fibers 120 may be arranged in a shape having a predetermined pattern, for example, in a mesh or web shape.

The coaxial double-layered fiber 120 may have the remaining charge even after being spinned. Thus, the spinning solution 60 may be discharged from the spinning nozzle 20 so that coaxial double-layered fibers 120 may be arranged in a random direction or a desired, predetermined direction.

The coaxial double-layered fiber 120 may have a double-layered structure including the nanomaterial layer 140 formed from the second spinning solution 64 and disposed inside the coaxial double-layered fiber 120 and the polymer material layer 130 formed from the first spinning solution 62 and disposed outside the nanomaterial layer 140, as illustrated in FIG. 10. Also, the nanomaterial layer 140 and the polymer material layer 130 may be disposed in a coaxial cylinder shape.

The polymer solution and the polymer material layer 130 formed from the polymer solution may include various polymer materials. For example, the polymer material layer 130 may include at least one selected from the group consisting of polyvinylpyrrolidone (PVP), polyvinyl alcohol (PVA), polymethyl methacrylate (PMMA), polydimethylsiloxane (PDMS), polyurethane, polyether urethane, cellulose acetate, cellulose acetate butyrate, cellulose acetate propionate, polymethyl acrylate (PMA), polyvinyl acetate (PVAc), polyacrylonitrile (PAN), polyfurfuryl alcohol (PPFA), polystyrene, polyethylene oxide (PEO), polypropylene oxide (PPO), polycarbonate (PC), polyvinyl chloride (PVC), polycaprolactone, polyvinyl fluoride, and polyimide.

In addition, the polymer solution and the polymer material layer 130 may include a copolymer of the above-described materials and at least one selected from the group consisting of a polyurethane copolymer, a polyacryl copolymer, a polyvinyl acetate copolymer, a polystyrene copolymer, a polyethylene oxide copolymer, a polypropylene oxide copolymer, and a polyvinylidene fluoride copolymer.

Also, the polymer solution and the polymer material layer 130 may include a polymer solution in which the above-described polymer materials are dissolved in a soluble solvent, such as methanol, acetone, tetrahydrofuran, toluene, or dimethylformamide. For example, the soluble solvent may include various materials including alkanes, such as hexane, aromatics, such as toluene, ethers, such as diethyl ether, alkyl halides, such as chloroform, esters, aldehydes, ketones, amines, alcohols, amide, carboxylic acids, and water. Also, the polymer solution may be formed using an organic solvent that will be described later. However, the polymer solution is exemplary, and the technical spirit of the invention is not limited thereto.

In addition, the nanomaterial solution and the nanomaterial layer 140 formed from the nanomaterial solution may include a conductive material, for example, a metal to nanomaterial or carbon nanotubes. The nanomaterial and the nanomaterial layer 140 may include at least one selected from the group consisting of silver (Ag), copper (Cu), cobalt (Co), scandium (Sc), titanium (Ti), chrome (Cr), manganese (Mn), iron (Fe), nickel (Ni), Cu, zinc (Zn), yttrium (Y), zirconium (Zr), niobium (Nb), molybdenum (Mo), technetium (Tc), ruthenium (Ru), rhodium (Rh), palladium (Pd), cadmium (Cd), hafnium (Hf), tantalum (Ta), tungsten (W), rhenium (Re), osmium (Os), iridium (Ir), platinum (Pt), gold (Au), mercury (Hg), lanthanide, actinoid, silicon (Si), germanium (Ge), tin (Sn), arsenic (As), antimony (Sb), bismuth (Bi), gallium (Ga), and indium (In).

The nanomaterial and the nanomaterial layer 140 may include various materials having nano-shapes, for example, at least one selected from the group consisting of nanoparticles, nanowires, nanotubes, nanorods, nanowalls, nanobelts, and nanorings.

The nanomaterial and the nanomaterial layer 140 may include nanoparticles, such as Cu, Ag, Au, a copper oxide, and Co. The nanomaterial and the nanomaterial layer 140 may include nanowires, such as Cu nanowires, Ag nanowires, Au nanowires, and Co nanowires.

Also, the nanomaterial and the nanomaterial layer 140 may include a nanomaterial solution in which the above-described nanomaterials are dissolved in a soluble solvent, such as methanol, acetone, tetrahydrofuran, toluene, or dimethylformamide. For example, the soluble solvent may include various materials, such as alkanes, such as hexane, aromatics, such as toluene, ethers, such as diethyl ether, alkyl halides, such as chloroform, esters, aldehydes, ketones, amines, alcohols, amide, carboxylic acids, and water. Also, the nanomaterial solution may be formed using an organic solvent that will be described later. However, the nanomaterial and the nanomaterial layer 140 are exemplary, and the technical spirit of the invention is not limited thereto.

Referring to FIG. 6, an operation S120 of separating the coaxial double-layered fiber 120 of FIG. 1 from the first substrate 100 and transferring the coaxial double-layered fiber 120 of FIG. 1 onto the second substrate 120 is performed.

In detail, the transferring operation may be performed, for example, in such a way that the second substrate 150 is disposed below the first substrate 100, the second substrate 150 is lifted, the coaxial double-layered fiber 120 is separated from the first substrate 100 and the coaxial double-layered fiber 120 is disposed on the second substrate 150.

Also, the transferring operation may be performed in such a way that the coaxial double-layered fiber 120 is first separated from the first substrate 100 and the coaxial double-layered fiber 120 is seated on the second substrate 150.

Also, the coaxial double-layered fiber 120 may be cut to be suitable for the size of the second substrate 150.

The second substrate 150 may include a transparent material through which light transmits. Also, the second substrate 150 may include a material through which light having a desired wavelength passes selectively. The second substrate 150 may include glass, quartz, a silicon oxide, an aluminum oxide, or polymer, for example. For example, the second substrate 150 may include polyimide, polyethylenenaphthalate (PEN), polyethyleneterephthalate (PET), PMMA, or PDMS. The second substrate 150 may include an elastic body, for example, and may include a flexible material, for example. Thus, the manufactured transparent electrode may have flexible characteristics. Also, the case where the second substrate 150 includes an opaque material, such as silicon wafer, is included in the technical spirit of the invention.

Referring to FIG. 7, an operation S130 of annealing the coaxial double-layered fiber 120 of FIG. 1 is performed. The annealing operation may increase a coupling force between nanomaterials in the nanomaterial layer 140. The annealing operation may be performed in the range of temperature in which the second substrate 150 is not damaged. The annealing operation may be performed at the temperate in the range of about 20° C. to about 500° C., for example, in the range of about 20° C. to about 300° C. The annealing operation may be performed in an air atmosphere, an inert atmosphere including an argon (Ar) gas or a nitrogen (N) gas, or a reducing atmosphere including a hydrogen (H) gas. The annealing operation is optional and may be omitted.

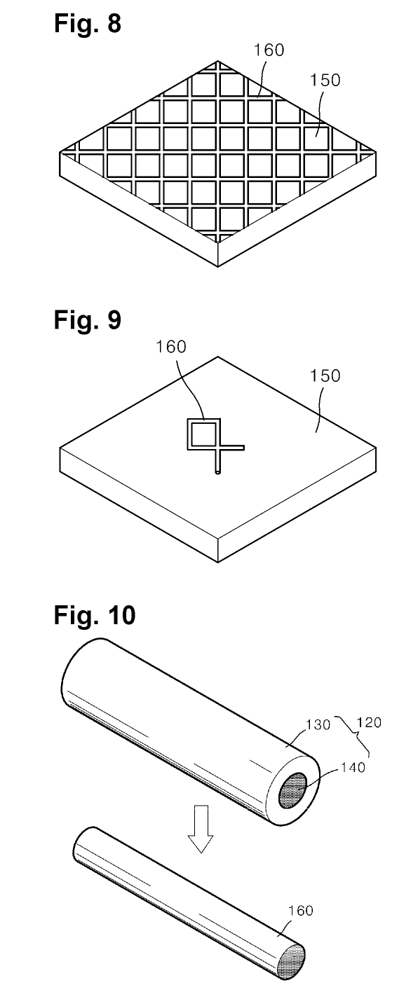

Referring to FIG. 8, an operation S140 of forming a transparent electrode 160 including the nanomaterial by removing the polymer material of FIG. 1 is performed.

As described above, because, in the coaxial double-layered fiber 120, the polymer material layer 130 is formed by surrounding the outside of the nanomaterial layer 140, when the polymer material layer 130 is removed, the transparent electrode 160 may include only the nanomaterial layer 140, and the transparent electrode 160 may have a full rod shape. Also, the transparent electrodes 160 may have an arrangement of the coaxial double-layered fiber 120 and may be arranged to configure a one-dimensional, two-dimensional, or three-dimensional conductive network structure in which coaxial double-layered fibers overlap one another and are connected to one another. Due to this network structure, the transparent electrode 160 may obtain predetermined conductivity. Also, the transparent electrodes 160 may be arranged in a shape having a predetermined pattern, for example, a mesh or web shape.

The polymer material layer 130 may be removed using an organic solvent. The organic solvent may include all types of solvents in which the polymer material layer 130 can be dissolved. The organic solvent may include various materials including alkanes, such as hexane, aromatics, such as toluene, ethers, such as diethyl ether, alkyl halides, such as chloroform, esters, aldehydes, ketones, amines, alcohols, carboxylic acids, and water. The organic solvent may include at least one selected from the group consisting of, for example, acetone, fluoroalkanes, pentanes, hexane, 2,2,4-trimethylpentane, decane, cyclohexane, cyclopentane, diisobutylene, 1-pentene, carbon disulfide, carbon tetrachloride, 1-chlorobutane, 1-chloropentane, xylene, diisopropyl ether, 1-chloropropane, 2-chloropropane, toluene, chlorobenzene, benzene, bromoethane, diethyl ether, diethyl sulfide, chloroform, dichloromethane, 4-methyl-2-propanone, tetrahydrofuran, 1,2-dichloroethane, 2-butanone, 1-nitropropane, 1,4-dioxane, ethyl acetate, methyl acetate, 1-pentanol, dimethyl sulfide, aniline, diethylamine, nitromethane, acetonitrile, pyridine, 2-butoxyethanol, 1-propanol, 2-propanol, ethanol, methanol, ethylene glycol, and acetic acid.

Also, the polymer material layer 130 may be removed using reactive ion etching.

After the annealing operation S130 is performed, the operation S140 of removing the polymer material may be performed. Alternatively, after the operation S140 of removing the polymer material is performed, an annealing operation of annealing the nanomaterial layer 140 that constitutes the transparent electrode 160 may be performed.

Referring to FIG. 9, the transparent electrode 160 may be cut to have a desired size using various methods including physical cutting, laser processing, chemical etching, or lift-off.

FIG. 10 is a schematic view illustrating a process of manufacturing the transparent electrode 160 in the method S100 of manufacturing the transparent electrode of FIG. 1, according to an embodiment of the present invention.

Referring to FIG. 10, as described with reference to FIG. 5, the coaxial double-layered fiber 120 is formed. The coaxial double-layered fiber 120 may have a shape of a coaxial cylinder in which the nanomaterial layer 140 is disposed inside the coaxial double-layered fiber 120 and the polymer material layer 130 is surrounded by the nanomaterial layer 140 and disposed outside the nanomaterial layer 140.

Subsequently, as described with reference to FIG. 8, the polymer material layer 130 is removed, thereby forming the transparent electrode 160 including the nanomaterial layer 140. The transparent electrode 160 may have a rod shape in which a central part of the transparent electrode 160 is full.

In the above-described embodiment, in the coaxial double-layered fiber 120, the nanomaterial layer 140 is disposed inside the coaxial double-layered fiber 120, and the polymer material layer 130 is disposed outside the nanomaterial layer 140, and the resultant transparent electrode 160 has a rod shape. However, the technical spirit of the invention is not limited thereto.

FIG. 11 is a schematic view illustrating a process of manufacturing the transparent electrode 160.

Referring to FIG. 11, as described with reference to FIG. 5, a coaxial double-layered fiber 120a is formed. In the current embodiment, the coaxial double-layered fiber 120a may have a shape of a coaxial cylinder in which a polymer material layer 130a formed from the polymer material is disposed inside the coaxial double-layered fiber 120a and a nanomaterial layer 140a formed from the nanomaterial is surrounded by the polymer material layer 130a and disposed outside the polymer material layer 130a. In this case, in the electrospinning apparatus 1 of FIG. 2, a nanomaterial solution may be used in and spinned on the first spinning solution tank 12, the first spinning nozzle 22, and the first spinning nozzle tip 32, and a polymer material solution may be used in and spinned on the second spinning solution tank 14, the second spinning nozzle 24, and the second spinning nozzle tip 34.

When a transparent electrode 160a including the nanomaterial layer 140a is formed by removing the polymer material layer 130a, the transparent electrode 160a may have a hollow shape.

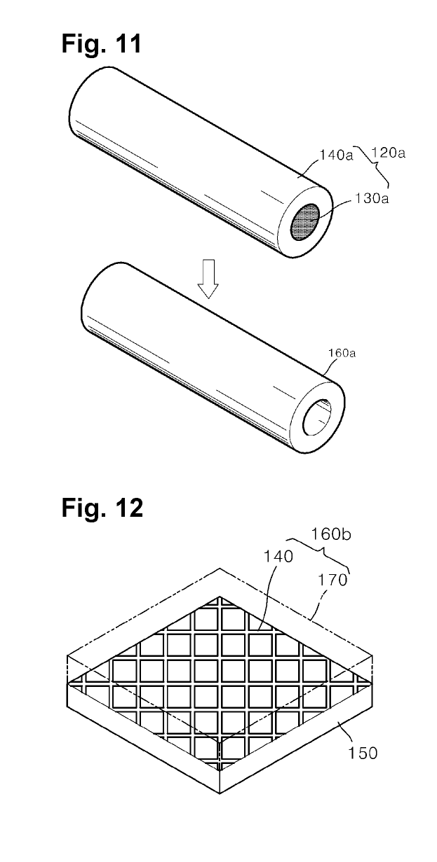

FIG. 12 is a schematic view illustrating a transparent electrode 160b formed by the method of manufacturing the transparent electrode of FIG. 1, according to an embodiment of the present invention.

Referring to FIG. 12, in comparison with the transparent electrode 160 of FIG. 8, the transparent electrode 160b further includes a transparent conductive layer 170 formed on the nanomaterial layer 140. That is, after the polymer material layer 130 in the operation S140 of FIG. 1 is removed using an organic solvent, an operation of forming the transparent conductive layer 170 on the nanomaterial layer 140 may be further performed.

The transparent conductive layer 170 may include a transparent material and may further include a conductive material. The transparent conductive layer 170 may reduce an electrical resistance of the transparent electrode 160b and may implement an electrode that more uniformly applies more current. The transparent conductive layer 170 may cover the transparent electrode 160b. Thus, the nanomaterial layer 140 may be blocked from an external air so that oxidation of the nanomaterial layer 140 may be prevented. When the nanomaterial layer 140 is formed of metal that is vulnerable to oxidation, such as Cu or Ag, the transparent conductive layer 170 may be effective for oxidation prevention.

The transparent conductive layer 170 may include a two-dimensional nanomaterial layer having conductivity. The two-dimensional nanomaterial layer may include two-dimensional nanomaterials, for example, graphene, graphite, or carbon nanomaterials, such as carbon nanotubes. The meaning of the two-dimensional nanomaterial is that the nanomaterial has a planar shape, for example, a shape of a sheet.

The graphene is a carbon nanostructure having a two-dimensional shape, and it is known that the graphene has large charge mobility of about 15,000 cm²/Vs and high thermal conductivity. It is also known that the graphene has excellent light transmittance. The graphene layer may be formed using various methods. For example, the graphene layer may be formed by mechanical delamination from graphite crystals or electrostatic delamination. Alternatively, the graphene layer may be formed by thermal decomposition of a silicon carbide, an extraction method using an oxidizing agent, such as hydrazine (NH₂NH₂), as a solvent, or chemical vapor deposition (CVD) using a reaction gas including hydrogen (H) and carbon (C).

The transparent conductive layer 170 including the graphene layer may be transferred onto the nanomaterial layer 140 using various methods. For example, soft transfer printing, a PDMS transfer method, a PMMA transfer method, a thermal dissipation tape transfer method, or a roll transfer method may be used.

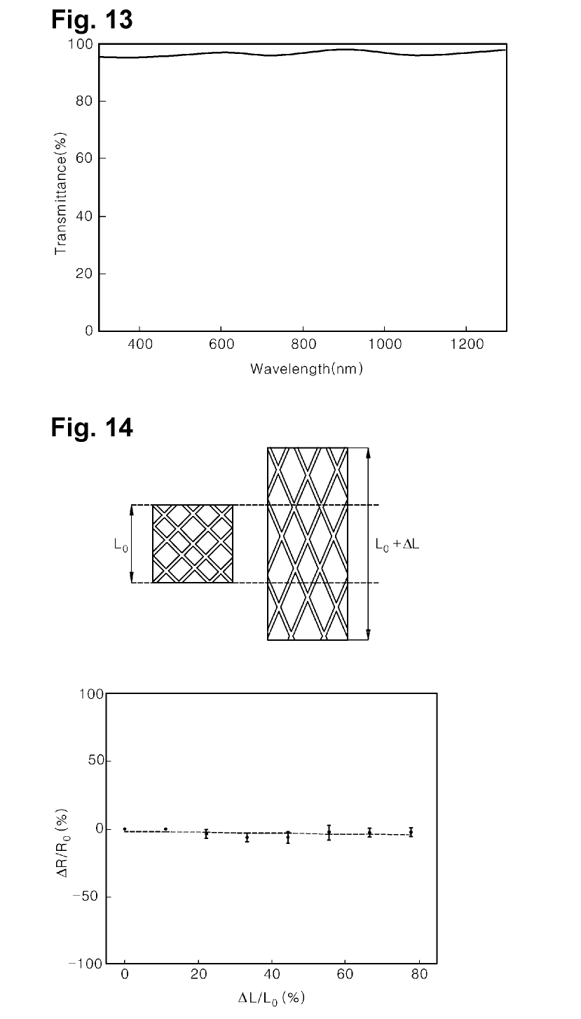

FIG. 13 is a graph showing transmittance versus an optical wavelength of the transparent electrode manufactured by the method of manufacturing the transparent electrode, according to an embodiment of the present invention.

Referring to FIG. 13, compared to glass, the transparent electrode shows transmittance of about 95% or more with respect to the entire wavelength of light. Thus, the transparent electrode may have excellent optical characteristics in all wavelength regions of light. Thus, the transparent electrode may be applied to electronic apparatuses that require transparency of an electrode.

FIG. 14 is a graph showing a change in resistances according to a degree of tension of the transparent electrode manufactured by the method of manufacturing the transparent electrode, according to an embodiment of the present invention.

Referring to FIG. 14, the relationship of resistance ΔR changed with respect to an original resistance Ro of the transparent electrode that changes as the transparent electrode having an original length Lo has a tensile length ΔL due to a tensile force. The resistance of the transparent electrode was hardly changed even though its length was changed. In particular, even when the transparent electrode has a change in lengths of about 80%, there was almost no change in resistances. The transparent electrode may be applied to electronic apparatuses that require flexibility of an electrode.

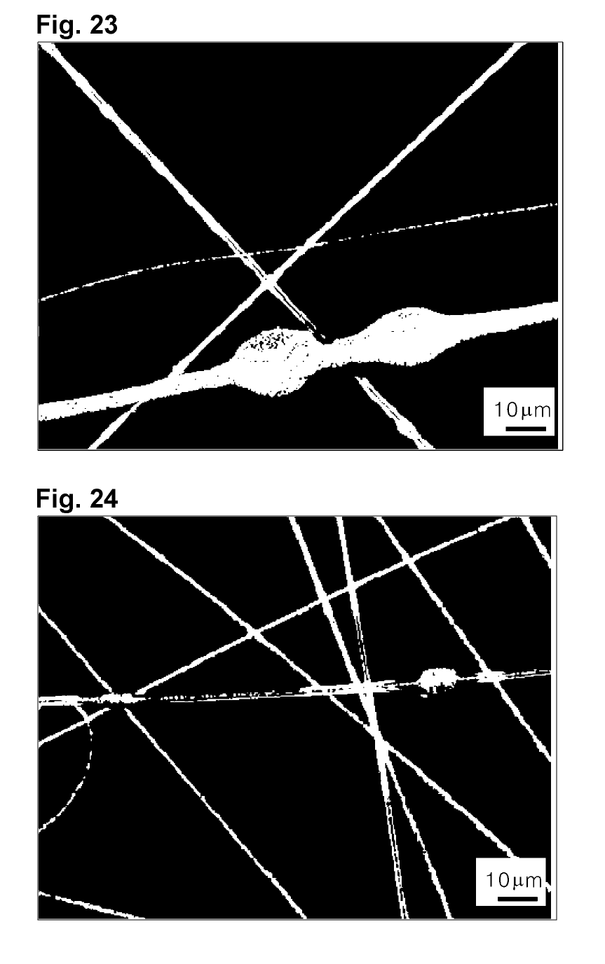

FIGS. 15 through 30 are optical microscopic photos showing the transparent electrode manufactured by the method of manufacturing the transparent electrode, according to an embodiment of the present invention.

FIGS. 15 through 20 show the case where the transparent electrode is formed using PVP as the polymer material layer and copper nanoink as the nanomaterial layer.

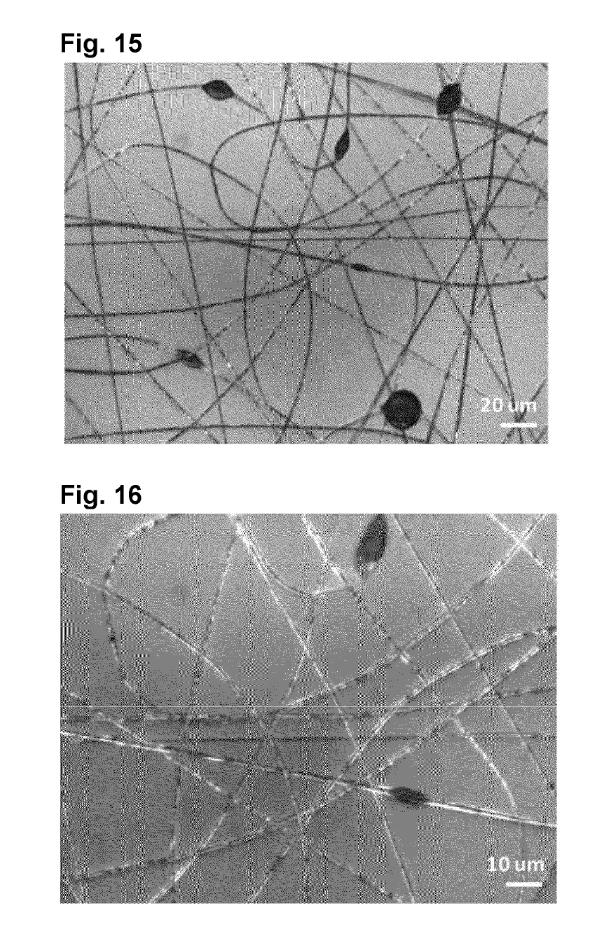

Referring to FIGS. 15 and 16, a coaxial double-layered fiber in which a nanomaterial layer formed using copper nanoink is formed inside the coaxial double-layered fiber and a polymer material layer formed using PVP is formed outside the nanomaterial layer, is shown. The coaxial double-layered fibers are arranged to overlap one another.

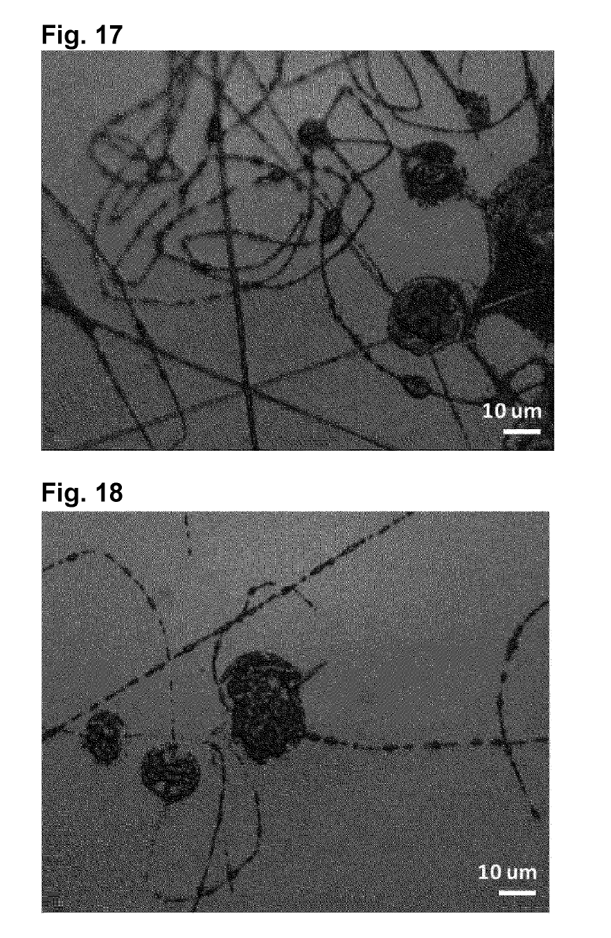

Referring to FIGS. 17 and 18, the coaxial double-layered fiber of FIGS. 15 and 16 in which the polymer material layer is removed by reactive ion etching and then the nanomaterial layer is exposed, is shown. The nanomaterial layer has been formed using copper nanoink and thus includes Cu. The nanomaterial layers are arranged to overlap one another even after reactive ion etching is performed.

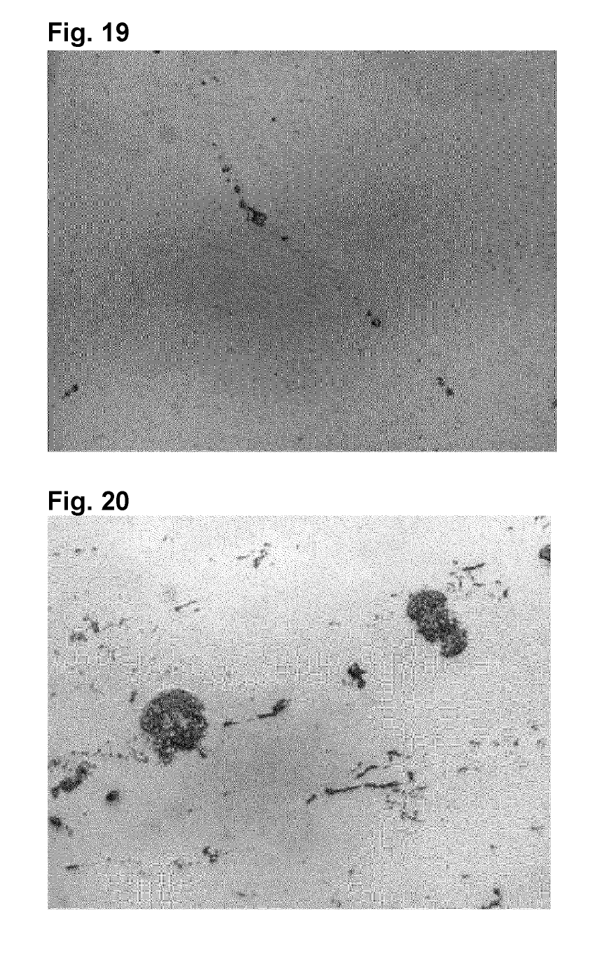

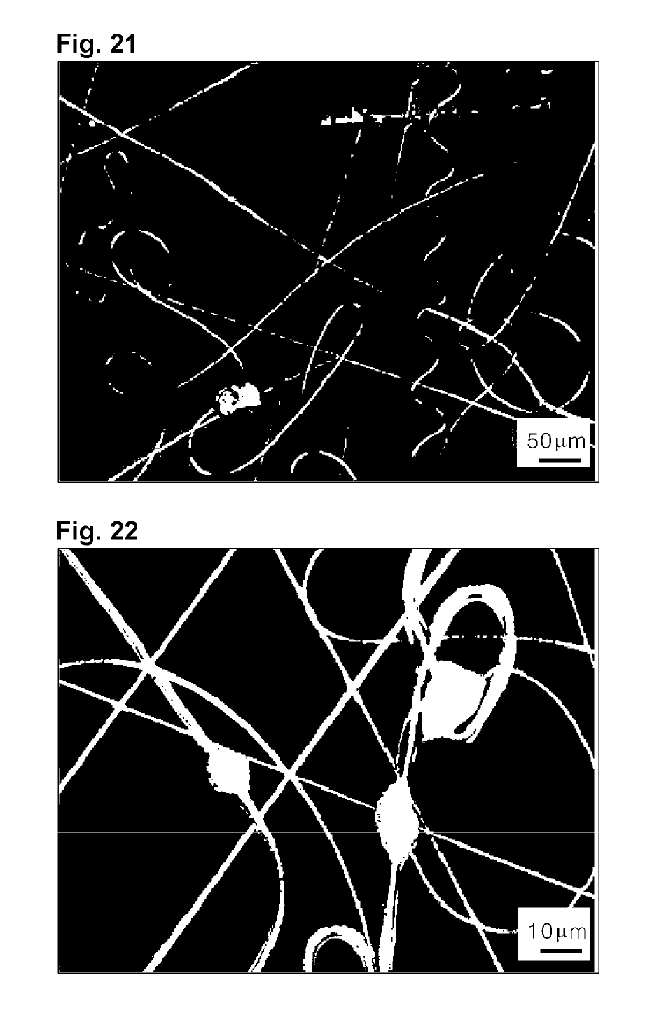

Referring to FIGS. 19 and 20, the coaxial double-layered fiber of FIGS. 15 and 16 in which the polymer material layer is removed using isopropyl alcohol (IPA) as an organic solvent and then the nanomaterial layer is exposed, is shown. The nanomaterial layer has been formed using copper nanoink and thus includes Cu. The nanomaterial layers are arranged to overlap one another even after removal using an organic solvent is performed.

FIGS. 21 through 30 illustrate the case where the transparent electrode is formed using PVP as the polymer material layer and Ag nanoink as the nanomaterial layer.

Referring to FIGS. 21 through 24, a coaxial double-layered fiber in which a nanomaterial layer formed using Ag nanoink is formed inside the coaxial double-layered fiber and a polymer material layer formed using PVP is formed outside the nanomaterial layer, is shown. The coaxial double-layered fibers are arranged to overlap one another.

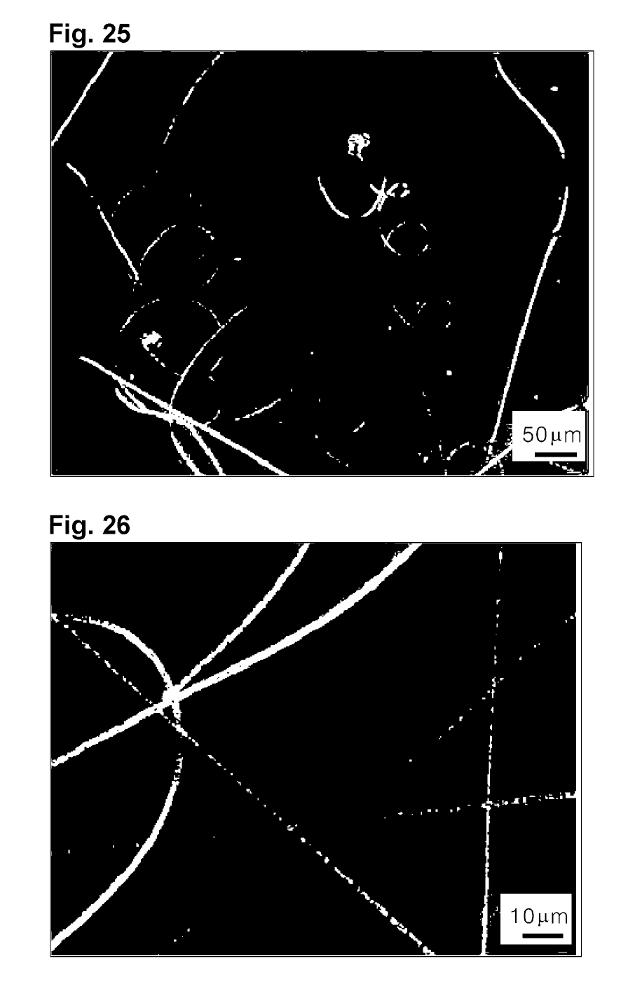

Referring to FIGS. 25 and 26, the coaxial double-layered fiber of FIGS. 21 through 24 in which the polymer material layer is removed using reactive ion etching and then the nanomaterial layer is exposed, is shown. The nanomaterial layer has been formed using Ag nanoink and thus includes Ag. The nanomaterial layers are arranged to overlap one another even after reactive ion etching is performed.

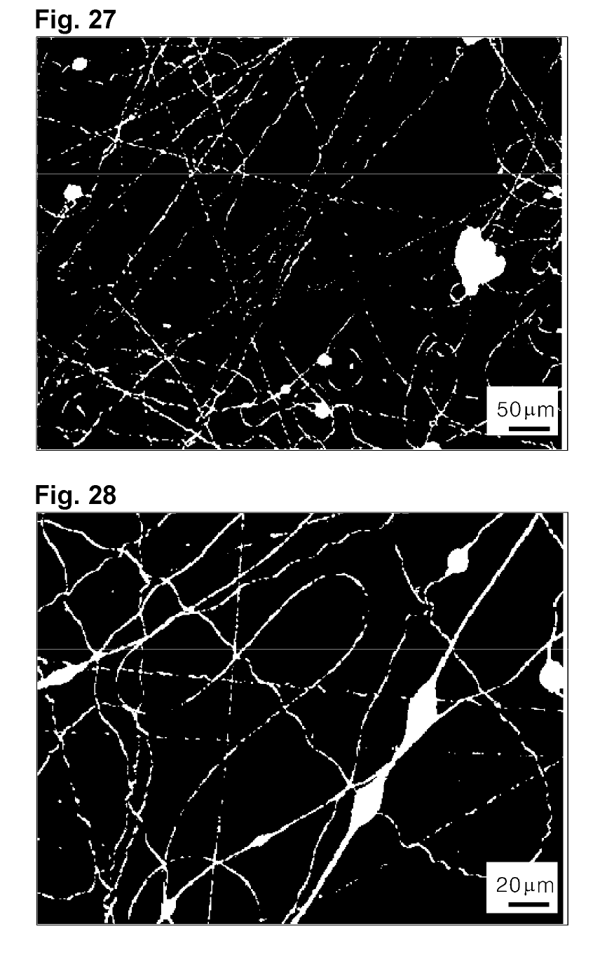

Referring to FIGS. 27 and 28, the coaxial double-layered fiber of FIGS. 21 through 24 in which the polymer material layer is removed using acetone as an organic solvent and then the nanomaterial layer is exposed, is shown. The nanomaterial layer has been formed using Ag nanoink and thus includes Ag. The nanomaterial layers are arranged to overlap one another even after removal using an organic solvent is performed.

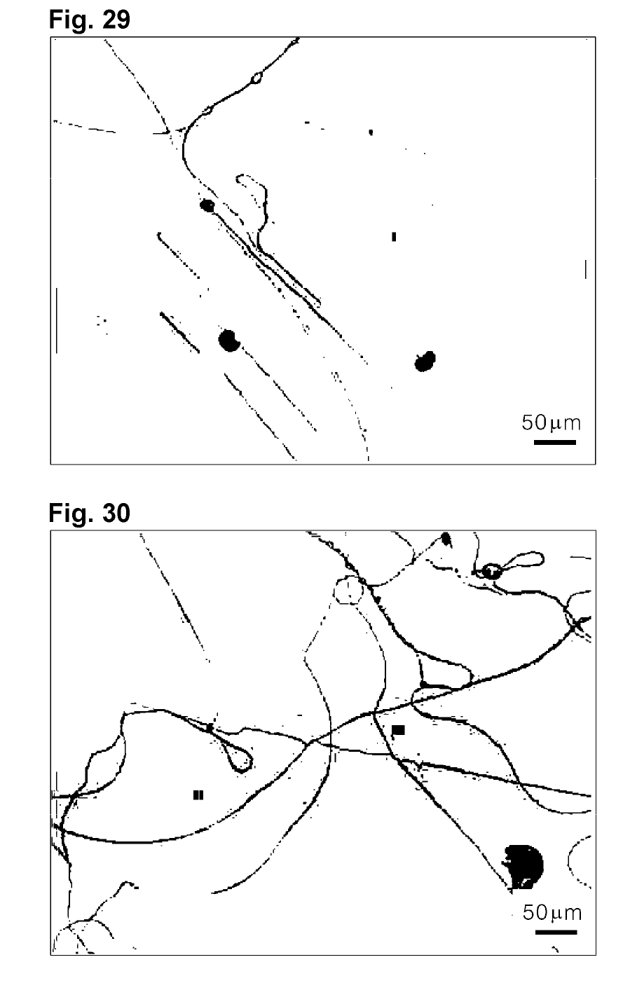

Referring to FIGS. 29 and 30, the coaxial double-layered fiber of FIGS. 21 through 24 in which the polymer material layer is removed using IPA as an organic solvent and then the nanomaterial layer is exposed, is shown. The nanomaterial layers are arranged to overlap one another even after removal using an organic solvent is performed.

As illustrated in FIGS. 15 through 30, in the method of manufacturing the transparent electrode according to the technical spirit of the invention, a nanomaterial layer that forms a network structure in which nanomaterial layers overlap one another, with respect to Cu nanoink and Ag nanoink can be implemented. Also, even after the polymer material layer is removed using reactive ion etching or IPA and acetone, a nanomaterial layer that forms a network structure in which nanomaterial layers overlap one another, can be implemented. Thus, various nanomaterial inks can be used, and the polymer material layer can be removed using various organic solvents so that the nanomaterial layer can be exposed, or the polymer material layer can be removed using various methods so that the nanomaterial layer can be exposed.

While the present invention has been particularly shown and described with reference to exemplary embodiments thereof, it will be understood by those of ordinary skill in the art that various changes in form and details may be made therein without departing from the spirit and scope of the present invention as defined by the following claims.

### INDUSTRIAL APPLICABILITY

By using the present invention, a transparent electrode having excellent light transmittance and elasticity can be manufactured.

1. A method of manufacturing a transparent electrode, the method comprising:
spinning a nanomaterial and a polymer material together on a first substrate to form a coaxial double-layered fiber including the nanomaterial and the polymer material; and
removing the polymer material from the coaxial double-layered fiber to form a transparent electrode including the nanomaterial.

2. The method of claim 1, wherein the forming of the coaxial double-layered fiber comprises spinning the nanomaterial and the polymer material together using an electrospinning method.

3. The method of claim 1, wherein the forming of the coaxial double-layered fiber comprises implementing the coaxial double-layered fiber having a shape of a coaxial cylinder in which a nanomaterial layer formed from the nanomaterial is disposed inside the coaxial double-layered fiber and a polymer material layer formed from the polymer material is surrounded by the nanomaterial layer and disposed outside the nanomaterial layer.

4. The method of claim 1, wherein the coaxial double-layered fiber is implemented as a coaxial double-layered fiber having a shape of a coaxial cylinder in which a polymer material layer formed from the polymer material is disposed inside the coaxial double-layered fiber and a nanomaterial layer formed from the nanomaterial is surrounded by the polymer material layer and disposed outside the polymer material layer.

5. The method of claim 1, wherein the forming of the coaxial double-layered fiber is performed by spinning the polymer material and the nanomaterial in a gel state on the first substrate.

6. The method of claim 1, wherein the forming of the coaxial double-layered fiber is performed by applying a voltage in the range of 100 V to 30000 V.

7. The method of claim 1, wherein the transparent electrode is arranged to configure a conductive one-dimensional, two-dimensional, or three-dimensional network structure formed in which the transparent electrode overlaps one another and is connected to one another.

8. The method of claim 1, wherein the transparent electrode is arranged to have a mesh or web shape.

9. The method of claim 1, wherein the nanomaterial comprises a conductive material.

10. The method of claim 1, wherein the polymer material has higher viscosity than the nanomaterial.

11. The method of claim 1, further comprising, after the forming of the coaxial double-layered fiber is performed, separating the coaxial double-layered fiber from the first substrate and transferring the coaxial double-layered fiber onto a second substrate.

12. The method of claim 1, further comprising, before the removing of the polymer material is performed, annealing the coaxial double-layered fiber.

13. The method of claim 1, further comprising, after the removing of the polymer material is performed, annealing the transparent electrode.

14. The method of claim 1, wherein the removing of the polymer material from the coaxial double-layered fiber is performed using an organic solvent or reactive ion etching.

15. The method of claim 1, further comprising, after the polymer material is removed, forming a transparent conductive layer on the nanomaterial layer.

16. The method of claim 15, wherein the transparent conductive layer comprises graphene, graphite, or carbon nanotubes.

17. The method of claim 1, wherein the first substrate is a free standing substrate.

18. The method of claim 1, wherein the first substrate has a shape in which a central part of the first substrate is perforated and outer edges thereof are connected to one another, or a shape in which a central part of the first substrate is perforated and outer edges thereof are not connected to one another.

19. A transparent electrode manufactured by the method of manufacturing the transparent electrode of claim 1.

20. The transparent electrode of claim 19, wherein the transparent electrode has a full rod shape.

21. The transparent electrode of claim 19, wherein the transparent electrode has a hollow shape.

22. An electrospinning apparatus for manufacturing a transparent electrode, in which a first spinning solution and a second spinning solution that are different from each other are spinned together to form a coaxial double-layered fiber, the electrospinning apparatus comprising:
a first spinning nozzle spinning the first spinning solution and disposed outside a spinning nozzle; and
a second spinning nozzle spinning the second spinning solution, being surrounded by the first spinning nozzle and disposed inside the first spinning nozzle.
